(19) United States
(12) Patent Application Publication
(10) Pub. No.: US 2022/0408566 A1
(43) Pub. Date: Dec. 22, 2022

(54) INTEGRATED MINIATURE WELDING PLATE STRUCTURE AND MANUFACTURING PROCESS THEREFOR

(71) Applicant: SCIVITA MEDICAL TECHNOLOGY CO., LTD., Suzhou (CN)

(72) Inventor: Yi ZHANG, Suzhou (CN)

(73) Assignee: SCIVITA MEDICAL TECHNOLOGY CO., LTD., Suzhou (CN)

(21) Appl. No.: 17/777,299

(22) PCT Filed: Nov. 18, 2019
(86) PCT No.: PCT/CN2019/119189

§ 371 Date: May 17, 2022

(51) Int. Cl. H05K 3/42

(52) U.S. Cl. CPC H05K 3/423; H05K 2203/122; H05K 2203/107; C25D 7/12

(57) ABSTRACT

The present invention discloses an integrated miniature welding plate structure and manufacturing process therefor, which consists of pads with welded dots, welding wires and a welding plate; the manufacturing process of the welding plate consists of following steps: S1. Punching holes, take a SMT patch fixed with several welding plates, punch holes in the welding plates in accordance with the requirements; S2 Electroplating, electroplate a metal layer with electroplating process onto the inner walls of the holes in each of the welding plates; S3. Gluing, pour the insulation colloid into the holes in each of the welding plates, then electroplate a metal layer onto both ends of the colloid; S4. Cutting, cut each of the welding plates off the patch. The beneficial effects are: the welding wires are welded with the welding plates, then the welding plates are connected with the welded dots of the to-be-welded parts, the adopted welding method of the welding plates can improve the overall welding efficiency, ensure the welding strength of the welded dots and improve the welding quality; the structure design of the base plate and vertical plate is adopted for the welding plates, the welding wires are welded onto the vertical plates in a centralized manner, so the status that the welding wires not being parallel and upright can be obviously improved.

### TECHNICAL FIELD

The present invention relates to the field of electronics welding process, particularly integrated miniature welding plate structure and manufacturing process therefor.

### BACKGROUND TECHNOLOGY

With the rapid development of electronic information, electronic devices and parts are developed towards refinement, miniaturization and modularization. Commonly used electronic parts can be connected through wires, however, welding miniature electronic parts or module parts is not easy.

About the electronic parts with miniature welded dots, such as CMOS camera or PCB, welded dots are usually only 0.3 mm; moreover, due to placement demands, it needs to be ensured that the welding wires connected to such electronic parts are vertical and parallel; however, during conventional welding, directly welding the welding wires with the welded dots may easily result in falling off of non-firm welded dots, as well as scattering and separation of several welding wires; it is obvious that conventional welding methods can't satisfy the miniature-electronic component welding needs.

### SUMMARY

The objective of the present invention is to solve the problem that conventional welding methods can't satisfy the electronic component welding needs, and to propose an integrated miniature welding plate, particularly an integrated miniature welding plate structure and manufacturing process therefor.

The technical scheme defined in the present invention to achieve above objective is, an integrated miniature welding plate structure and manufacturing process therefor, which consists of pads with welded dots, welding wires directly or indirectly connected with pads, a welding plate integrated with at least one welding hole for welding the welding wires with the pads, so that the welded dots on the pads and the welding wires are electrically conducted; the manufacturing process of the welding plate consists of following steps: S1. Punching holes, take a SMT patch fixed with several welding plates, punch holes in the welding plates in accordance with the requirements; S2. Electroplating, electroplate a metal layer with electroplating process onto the inner walls of the holes in each of the welding plates, such metal layer is a conductive layer for conducting the conductors on both sides of the welding plates; S3. Gluing, pour the insulation colloid into the holes in each of the welding plates, smooth flat, electroplate a metal layer onto both ends of the colloid, such metal layers are conductor layers for directly connecting the welded dots and the welding wires, the conductor layers contact with the conductive layer; S4. Cutting, cut each of the welding plates off the patch with a laser cutting machine.

As an optional embodiment of a welding plate structure, the welding plate consists of a base plate, at least one hole through both lateral sides of the base plate is arranged on the base plate, a metal conductor is arranged inside each of the hole, one ends of the metal conductors are connected with the welding wires, and the other ends are connected with the welded dots on the pads.

As another optional embodiment of a welding plate structure, the welding plate consists of a base plate and a vertical plate, at least one hole through both lateral sides of the base plate is arranged on the base plate, grooves corresponding to the number of the holes are arranged in the vertical plate, the metal conductors are arranged inside both the holes and the grooves, the conductors inside the holes and the grooves conduct with each other, the metal conductors inside the grooves are connected with the welding wires, and the metal conductors inside the holes are connected with the welded dots on the pads.

As a further limitation on a metal conductor structure, the end surfaces of the metal conductors used to connect with the welded dots are flat, and the area of the end surfaces of the metal conductors used to weld with the welding wires can be bigger than that of the end surfaces of the metal conductors used to weld with the welded dots.

As an optional embodiment of gluing process, the gluing step in the welding plate manufacturing process can also be, firstly electroplate a metal layer onto one lateral sides of the welding plates to plate one sides of the holes with the metal layer, then pour the insulation colloid with a PCB glue machine into the holes, smooth flat, and electroplate again to form a flat metal layer on one lateral sides of the welding plates.

As a further limitation on the arrangement mode of the welding plates on the patch, the welding plates are uniformly arranged on the SMT patch, the holes can be punched on the welding plates with an auto punch.

As an optional embodiment of the method for punching holes in the welding plates, the auto punch can be a drilling machine or a laser punch, hole spacing errors and hole diameter errors are not bigger than 0.05 mm.

As a further limitation on the thickness of an electroplated conductive layer, the conductive layer is electroplated inside the holes in the welding plates, it is required that the holes shall not be blocked by the conductive layer, and the middle gaps are reserved for pouring the insulation colloid.

As a further limitation on a connection between the conductor layers and the conductive layer, the conductor layers are on both sides of the holes in the welding plates, the conductor layers on both sides of the holes in the welding plates electronically conduct with each through the conductive layer between such conductor layers, so a current path is formed among the welding wire, the conductor layer, the conductive layer and the conductor layer.

As a further description of a patch cutting process, before cutting the patch, cutting lines can be arranged on the surface of the patch, then by laser cutting, the patch can be cut into several welding plates of the same size, and the numbers of the holes in the welding plates on the patch can be different.

The beneficial effects are: 1. The welding wires are welded with the welding plates, then the welding plates are connected with the welded dots of the to-be-welded parts, the adopted welding method of the welding plates can improve the overall welding efficiency, ensure the welding strength of the welded dots and improve the welding quality. Several welded dots are integrated on the welding plates to connect with the welding wires, since the welding plates are not the to-be-welded parts, the areas of the conductor layers on the welding plates can be bigger for finding the welding positions during welding, in addition, since the welding wires can be welded onto the welding plates in advance, the possible damages caused to the welded dots of the to-be-welded parts due to directly welding the welding wires with the to-be-welded parts can be prevented, the welding wires can be welded and fixed onto the welding plates in an centralized manner, and then connected with the to-be-welded parts, so the overall welding efficiency can be improved.

2. The structure design of the base plate and vertical plate is adopted for the welding plates, the welding wires are welded onto the vertical plates in a centralized manner, so the status that the welding wires not being parallel and upright can be obviously improved. About the narrow and long CMOS camera, its wires can't be too scattered, such wires take space and hinder the assembling of other parts, the grooves are arranged in the vertical plate, and then the wires and the metal conductors inside the grooves are welded together; on one hand, the contact mode is changed from dot-with-surface into surface-with-surface, welding areas are enlarged, and welding strength is improved; on the other hand, all grooves are parallel upright, after being welded, the arrangement mode of the wires is accordingly parallel upright, that is, the wire arrangement needs are conveniently satisfied.

### DESCRIPTION OF THE DRAWINGS

FIG. 1 is a structural view of an embodiment of the welding plate in the present invention;

FIG. 2 is a structural view of the structure as shown in FIG. 1 with welded welding wires;

FIG. 3 is a sectional view of a single hole in the welding plate;

FIG. 4 is a structural view of another embodiment of the welding plate in the present invention;

FIG. 5 is a structural view of the structure as shown in FIG. 4 with welded welding wires;

FIG. 6 is a structural view of the structure as shown in FIG. 4 cooperating with the to-be-welded part;

In figures, 1. Welding plate; 2. Conductive layer; 3. Conductor layer; 4. Insulation colloid; 5. Welding wire; 6. Base plate; 7. Vertical plate; 8. Groove; 9. Metal conductor; 10. To-be-welded part; 11. Pad.

### DESCRIPTION OF EMBODIMENTS

Firstly, the original design intention of the welding plate 1 is that, in actual work, especially for miniature-electronic components, there are following difficulties when welding wires of such electronic components:

1. The electronic components are miniature, the welded dots are smaller, welding positions can't be quickly located when welding the wires with the welded dots, especially when several welded dots are arranged in a centralized manner, welding mistakes may easily occur; in addition, since the welding areas are small, welded sections may get loose due to non-firm welding.

2. Miniature-electronic components are usually assembled onto small products, so the parts inside such products must be arranged in a compact and centralized manner, however, when welding the wires, the directions of the wires can't be controlled, if the directions of the wires are forcibly changed after welding, the welded dots may easily fall of, so it is required to slowly and carefully weld the wires, and the welding efficiency is reduced.

In order to avoid the above situation, the present invention proposes an integrated miniature welding plate 1, by welding the wires onto one plate in a centralized manner and then welding the plate with the to-be-welded part 10, since the plate is not a to-be-welded part 10, the structure design can fit to the welding needs as much as possible, such as increasing the contact areas on the welded dots and adding auxiliary straightening structures, so the problems of difficult welding due to small welding areas and scattered welding wires 5 can be optimized.

The specific structure of the welding plate 1 defined in the present invention is described below through two embodiments:

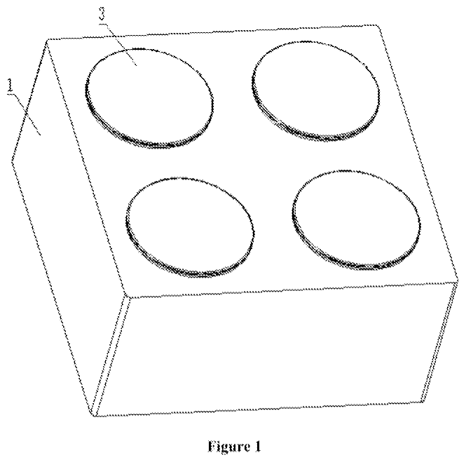

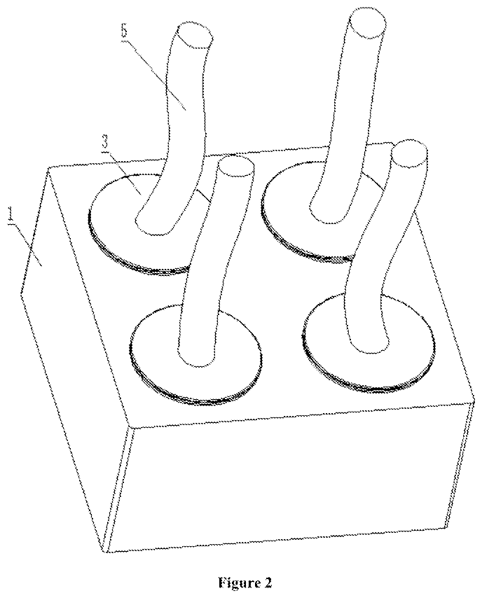

The first reference embodiment, as shown in FIGS. 1-2, the welding plate 1 consists of the base plate 6, 4 holes are arranged through the base plate 6, the metal conductor 9 is arranged inside each of the holes, the areas of the two end surfaces of the metal conductor 9 are different, the smaller end surface is used to weld with the to-be-welded part 10, the bigger end surface is used to weld with the wire, it can be seen from the Figures that, the end surface welded with the wire is obviously bigger than the other end surface, in another word, when welding with the welding plate 1 structure, the welding area on the wire is bigger than that of the wire directly welded onto the to-be-welded part 10, therefore, welding can be more convenient, contact areas on the welded dots can be enlarged, and the welding strength can be improved.

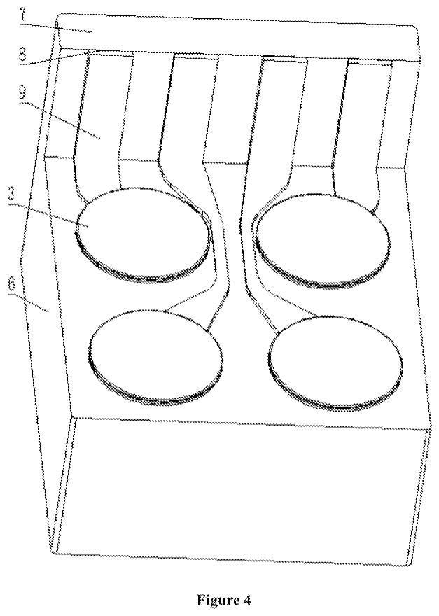

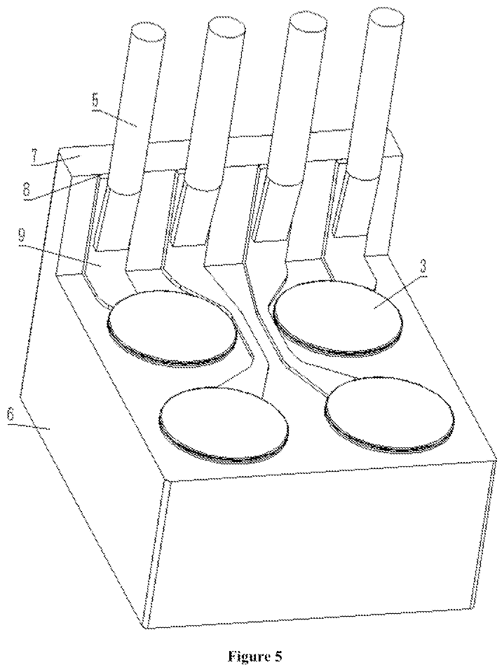

The second reference embodiment, as shown in FIGS. 4-5, the welding plate 1 consists of the base plate 6 and the vertical plate 7, the difference between this embodiment and the above embodiment is that, the vertical plate 7 structure is added, the function of the vertical plate 7 structure is to provide a “support” for the wires to stay upright, it can be seen from the Figures that, 4 grooves 8 are arranged in the vertical plate 7, the metal conductor 9 is arranged inside each of the grooves 8, the 4 grooves 8 correspond to the 4 holes in the base plate 6, the effects of welding the wires inside the grooves 8 in the vertical plate 7 and welding the wires inside the holes in the base plate 6 are equivalent, the advantage of setting the vertical plate 7 is that, since the structure of the vertical plate 7 is vertically arranged, the 4 grooves 8 are parallel, as same as the mode of setting the wires uprightly; therefore, by welding the wires into the grooves 8 in the vertical plate 7; therefore, by welding the wires into the grooves 8 in the vertical plate 7, the 4 wires are accordingly arranged in a parallel manner, the upright arrangement of the wires can be ensured conveniently; in addition, another advantage is that, the connection mode of the welded dots is changed from dot-with-surface welding between the top of the welding wire 5 and the welding surface into surface-with-surface welding between the lateral surface of the welding wire 5 and the welding surface, such welding method enlarges the connection areas on the welding surfaces, obviously improves the welding firmness, therefore realizes convenient welding, satisfies the welding requirement of parallel upright welding wires 5, and improves the overall welding efficiency and effects.

The overall structure of the welding plate 1 is described above, among which, the most important characteristic is that, the holes are arranged on the base plate 6, because it is well known that, during miniature-electronic component welding, when welding two modules, if the end surface of one welded end is not flat, that is, there are bumps or pits, edge warps will inevitably appear on the connection between the two modules, welded parts can't be aligned, and for the parts with compact structures, arrangements of other parts will be directly affected; the cause of uneven welding is the uneven welded dots, therefore, for the welding plates 1 defined in the present invention, it must be ensured that the end surfaces of the metal conductors 9 arranged inside the holes in the welding plates 1 are flat and without bumps or pits. A processing method of the welding plates 1 is described below to explain the manufacturing process of the welding plates 1 defined in the present invention.

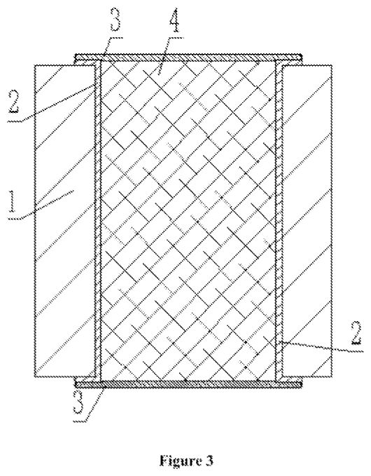

The manufacturing process of the welding plates 1 includes the following 4 steps, combining FIG. 3:

S1. Punching holes, take a SMT patch fixed with several welding plates 1, punch holes in each of the welding plates 1 with an auto punch, the punch can be a drilling machine, the hole diameter is 0.36 mm, hole spacing errors and hole diameter errors are not bigger than 0.05 mm;

S2 Electroplating, electroplate a metal layer with electroplating process onto the inner walls of the holes in each of the welding plates 1, such metal layer is a conductive layer 2 for conducting the conductors on both sides of the welding plates 1, it shall be noted that, during actual manufacturing, the conductive layer 2 is thin and meets the electric conduction need, if electroplating makes the plated layer too thick and even directly plates the holes, them will be circular bumps on both ends of the holes, the unevenness between the welding plates 1 and the to-be-welded parts 10 can't be prevented, so the conductive layer 2 must be thin, and this is the core of this manufacturing process;

S3. Gluing, since only a thin layer is electroplated during electroplating, it means that the middle sections of the holes are hollow, so such middle sections need to be glued to fill the hollowness, the following two gluing methods can be implemented: first, pour the insulation colloid 4 into the holes in each the welding plates 1, smooth flat, electroplate a metal layer onto both ends of the colloid, such metal layers are conductor layers 3 for directly connecting the welded dots and the welding wires 5, the conductor layers 3 contact with the conductive layer 2, compared with the second method, this method is quicker and more convenient, the both end surfaces are blocked at one time, second, firstly electroplate a metal layer onto one lateral sides of the welding plates 1 to plate one ends of the holes, then pour the insulation colloid 4 into the holes with a PCB glue machine, smooth flat, electroplate again to form a flat metal layer on one lateral sides of the welding plates 1, compared with the first method, the advantages of this method are that, the end surfaces blocked firstly can be used to weld with the wires, there is no need to ensure the evenness, the processing difficulty can be reduced, the end surfaces blocked secondly can be used to contact with the to-be-welded parts 10, since the gluing spaces will not change (the colloid is limited inside the holes and will not move randomly), the end surfaces will definitely be flat, and the gluing effects can be improved;

S4. Cutting, cut each of the welding plates off the patch with a laser cutting machine, in order improve cutting effects, cutting lines can be arranged on the patch in advance, then cut the patch into several welding plates 1 of the same size, according to actual needs, the holes in the welding plates 1 can be the same or different.

The actual application process in actual work of the welding plate 1 defined in the present invention is described below:

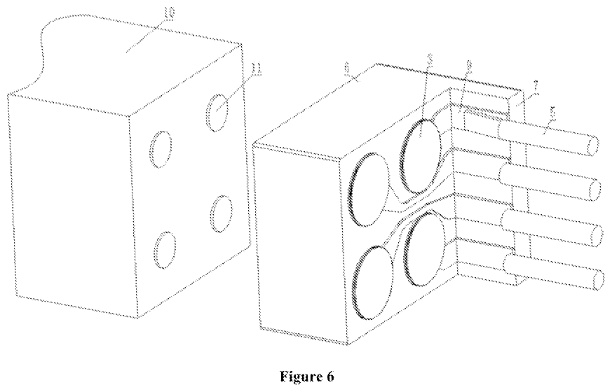

After the welding plates 1 are manufactured with the above process, take a welding plate 1 (with the structure as shown in FIG. 4), correspond the to-be-welded wires to the welded dots (as shown in FIG. 6, correspond each welded dot to the pads 11 on the to-be-welded part 10, so positions of the pads 11 corresponding to different wires need to be identified in advance), then weld the wires onto the metal conductors 9 on the vertical plate 7 to form the welding wires 5, it can be seen from the Figures that, the contact areas between the welding wires 5 and the metal conductors 9 are bigger than the contact areas shown in FIG. 2, the welding is firmer, after all welding wires 5 are welded, weld the entire welding plate 1 with the to-be-welded part 10, because it is a module welding method, welding single wires with single welded dots is not needed, so the welding is highly efficient and convenient.

The above technical scheme only reflects the preferred technical scheme of the technical scheme of the present invention, the changes in certain aspects of the technical scheme made by those skilled in the art reflect the principle of the present invention and fall into the protection scope of the present invention.

1. An integrated miniature welding plate structure and manufacturing process therefor, which consists of pads with welded dots, welding wires directly or indirectly connected with pads, which is featured by,
A welding plate integrated with at least one welding hole for welding the welding wires with the pads, so that the welded dots on the pads and the welding wires are electrically conducted;
The manufacturing process of the welding plate consists of following steps:
S1. Punching holes, take a SMT patch fixed with several welding plates, punch holes in the welding plates in accordance with the requirements;
S2. Electroplating, electroplate a metal layer with electroplating process onto the inner walls of the holes in each of the welding plates, such metal layer is a conductive layer for conducting the conductors on both sides of the welding plates;
S3. Gluing, pour the insulation colloid into the holes in each of the welding plates, smooth flat, electroplate a metal layer onto both ends of the colloid, such metal layers are conductor layers for directly connecting the welded dots and the welding wires, the conductor layers contact with the conductive layer,
S4. Cutting, cut each of the welding plates off the patch with a laser cutting machine.

2. An integrated miniature welding plate structure and manufacturing process therefor as recited in claim 1, which is featured by: the welding plate consists of a base plate, at least one hole through both lateral sides of the base plate is arranged on the base plate, a metal conductor is arranged inside each of the hole, one ends of the metal conductors are connected with the welding wires, and the other ends are connected with the welded dots on the pads.

3. An integrated miniature welding plate structure and manufacturing process therefor as recited in claim 1, which is featured by: the welding plate consists of a base plate and a vertical plate, at least one hole through both lateral sides of the base plate is arranged on the base plate, grooves corresponding to the number of the holes are arranged in the vertical plate, the metal conductors are arranged inside both the holes and the grooves, the conductors inside the holes and the grooves conduct with each other, the metal conductors inside the grooves are connected with the welding wires, and the metal conductors inside the holes are connected with the welded dots on the pads.

4. An integrated miniature welding plate structure and manufacturing process therefor as recited in claim 2, which is featured by: the end surfaces of the metal conductors used to connect with the welded dots are flat, and the area of the end surfaces of the metal conductors used to weld with the welding wires can be bigger than that of the end surfaces of the metal conductors used to weld with the welded dots.

5. An integrated miniature welding plate structure and manufacturing process therefor as recited in claim 1, which is featured by: the gluing step in the welding plate manufacturing process can also be, firstly electroplate a metal layer onto one lateral sides of the welding plates to plate one sides of the holes with the metal layer, then pour the insulation colloid with a PCB glue machine into the holes, smooth flat, and electroplate again to form a flat metal layer on one lateral sides of the welding plates.

6. An integrated miniature welding plate structure and manufacturing process therefor as recited in claim 1, which is featured by: the welding plates are uniformly arranged on the SMT patch, the holes can be punched on the welding plates with an auto punch.

7. An integrated miniature welding plate structure and manufacturing process therefor as recited in claim 6, which is featured by: the auto punch can be a drilling machine or a laser punch, hole spacing errors and hole diameter errors are not bigger than 0.05 mm.

8. An integrated miniature welding plate structure and manufacturing process therefor as recited in claim 1, which is featured by: the conductive layer is electroplated inside the holes in the welding plates, it is required that the holes shall not be blocked by the conductive layer, and the middle gaps are reserved for pouring the insulation colloid.

9. An integrated miniature welding plate structure and manufacturing process therefor as recited in claim 1, which is featured by: the conductor layers are on both sides of the holes in the welding plates, the conductor layers on both sides of the holes in the welding plates electronically conduct with each through the conductive layer between such conductor layers, so a current path is formed among the welding wire, the conductor layer, the conductive layer and the conductor layer.

10. An integrated miniature welding plate structure and manufacturing process therefor as recited in claim 1, which is featured by: before cutting the patch, cutting lines can be arranged on the surface of the patch, then by laser cutting, the patch can be cut into several welding plates of the same size, and the numbers of the holes in the welding plates on the patch can be different.
